(19) United States
(12) Patent Application Publication
(10) Pub. No.: US 2026/0293063 A1
(43) Pub. Date: Sep. 24, 2026

(54) VAPOR QUALITY CONTROL IN COOLING DISTRIBUTION UNIT

(71) Applicant: Advanced Liquid Cooling Technologies Inc., Anderson, SC (US)

(72) Inventors: Nan Chen, Alpharetta, GA (US); Yunshui Chen, Greer, SC (US)

(21) Appl. No.: 19/555,425

(22) Filed: Mar. 3, 2026

Related U.S. Application Data
(60) Provisional application No. 63/767,748, filed on Mar. 6, 2025.

(51) Int. Cl. H05K 7/20

(52) U.S. Cl. CPC H05K 7/20836; H05K 7/20318; H05K 7/20327; H05K 7/20809

(57) ABSTRACT

A cooling distribution unit for dual-phase cooling of electronic equipment may include a cooling loop configured to circulate a coolant to and from at least one heat source, a condenser configured to condense vaporized coolant into liquid coolant, a pump configured to deliver the liquid coolant to the heat source at a variable flow rate, a vapor quality sensor positioned downstream of the heat source and configured to measure a vapor quality of a liquid-vapor coolant mixture exiting the heat source, and control logic operatively coupled to the vapor quality sensor and the pump. The control logic may be configured to adjust the flow rate of the pump based at least in part on the measured vapor quality to maintain the vapor quality within a predetermined operating range. These improvements balance liquid mass flow with liquid cooling capacity in dual-phase cooling systems.

### PRIORITY

This patent application claims priority from Provisional U.S. Patent Application No. 63/767,748, filed Mar. 6, 2025, entitled VAPOR QUALITY CONTROL IN COOLING DISTRIBUTION UNIT and naming Nan Chen and Yunshui Chen as the inventors, the disclosure of which is incorporated herein in its entirety, by reference.

### FIELD

Illustrative embodiments of the invention generally relate to dual-phase cooling techniques for high power consumption electrical components and, more particularly, to vapor quality control in a cooling distribution unit.

### BACKGROUND

Data centers may include large numbers of computers, data storage, and networking resources. The computers are typically servers, each including one or more very powerful processors and significant memory resources. The servers consume significant amounts of power and produce a large amount of heat, which must be dealt with by the data center.

Information technology equipment continues to increase in power density, requiring more efficient cooling solutions. Conventional air cooling techniques are insufficient for modern data centers employing high-power CPUs and GPUs. Liquid and dual-phase cooling solutions have emerged but suffer from instability and inefficiencies under variable thermal loads.

### SUMMARY OF VARIOUS EMBODIMENTS

In accordance with one embodiment of the invention, a cooling distribution unit for dual-phase cooling of electronic equipment may include a cooling loop configured to circulate a coolant to and from at least one heat source, a condenser configured to condense vaporized coolant into liquid coolant, a pump configured to deliver the liquid coolant to the heat source at a variable flow rate, a vapor quality sensor positioned downstream of the heat source and configured to measure a vapor quality of a liquid-vapor coolant mixture exiting the heat source, and control logic operatively coupled to the vapor quality sensor and the pump. The control logic may be configured to adjust the flow rate of the pump based at least in part on the measured vapor quality to maintain the vapor quality within a predetermined operating range.

In accordance with other embodiments, the cooling distribution unit may include a first pressure sensor and a first temperature sensor positioned upstream of the heat source.

In accordance with other embodiments, the cooling distribution unit may include a second pressure sensor and a second temperature sensor positioned downstream of the heat source.

In accordance with other embodiments, the control logic adjusts the pump flow rate based on the vapor quality and one or more of a pressure differential or a temperature differential across the heat source.

In accordance with other embodiments, the control logic is configured to maximize the variable flow rate when a vapor core temperature of the coolant is higher than a saturation temperature of the coolant.

In accordance with other embodiments, the control logic increases the pump flow rate in response to an increase in vapor quality.

In accordance with other embodiments, the control logic reduces the pump flow rate in response to a decrease in vapor quality indicating excess liquid cooling capacity.

In accordance with other embodiments, the condenser is coupled to a refrigerant reservoir configured to store condensed liquid coolant.

In accordance with other embodiments, a subcooling loop may be configured to deliver subcooled liquid coolant to the pump.

In accordance with other embodiments, a method for controlling dual-phase cooling of electronic equipment may include supplying liquid coolant to a heat source using a variable-speed pump, transferring heat from the heat source to the coolant to generate a liquid-vapor coolant mixture, measuring a vapor quality of the coolant mixture downstream of the heat source, and dynamically adjusting a flow rate of the pump based at least in part on the measured vapor quality to regulate heat transfer performance of the heat source.

In accordance with other embodiments, adjusting the flow rate may be based on the measured vapor quality and one or more of the measured pressure or temperature.

In accordance with other embodiments, adjusting the flow rate maintains the vapor quality below a dry-out threshold.

In accordance with other embodiments, adjusting the flow rate maintains the vapor quality near a point of a maximum heat transfer coefficient.

In accordance with other embodiments, the method includes condensing vaporized coolant, storing the condensed coolant to a coolant reservoir, and recirculating the stored condensed coolant to the heat source.

In accordance with other embodiments, the pump flow rate is increased when vapor quality exceeds a predetermined upper limit.

In accordance with other embodiments, a control system for a dual-phase cooling loop may include an input configured to receive a vapor quality signal indicative of a vapor-to-liquid ratio of a coolant exiting a heat source, one or more inputs configured to receive one or more of pressure data or temperature data associated with the heat source, and a controller configured to generate a pump control signal that adjusts a coolant flow rate through the heat source based on the vapor quality signal and the pressure or temperature data.

In accordance with other embodiments, the controller may be configured to prevent flow instability associated with dual-phase boiling by modifying the pump control signal.

In accordance with other embodiments, the controller may be configured to adjust the flow rate to maintain the vapor-to-liquid ratio near a point of a maximum heat transfer coefficient for the coolant.

In accordance with other embodiments, the controller may be configured to optimize power usage effectiveness by reducing pump speed during partial thermal load conditions.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a schematic diagram of an example of a dual-phase cooling system in accordance with illustrated embodiments.

FIG. 2 schematically shows a schematic diagram of a dual-phase cooling system in accordance with illustrated embodiments.

FIG. 3 schematically shows a graph of critical points of dual-phase microchannel heat transfer in accordance with illustrated embodiments.

FIG. 4 schematically shows a channel demand curve in accordance with illustrated embodiments.

FIG. 5 schematically shows a schematic diagram of a dual phase cooling system employing vapor quality control in accordance with illustrated embodiments.

FIG. 6 shows a flowchart of a flow rate control process of a CDU in accordance with a first illustrated embodiment.

FIG. 7 shows a flowchart of a flow rate control process of a CDU in accordance with a second illustrated embodiment.

### DESCRIPTION OF ILLUSTRATIVE EMBODIMENTS

In illustrative embodiments, a cooling distribution unit (CDU) is configured for use in a data center or other electronic equipment environment having variable and often rapidly changing thermal loads. The CDU employs a dual-phase coolant that transitions between liquid and vapor phases as heat is absorbed from one or more heat sources, such as processors, accelerators, memory modules, or other high power-density electronic components.

In various embodiments, the disclosed vapor quality control techniques are not limited to data centers and may be applied to any thermal management system employing dual-phase or multi-phase heat transfer. Non-limiting examples include high-performance computing systems, artificial intelligence accelerators, telecommunications equipment, electric vehicle power electronics, battery thermal management systems, aerospace electronics, radar systems, industrial power converters, medical imaging systems, renewable energy inverters, laser systems, and other high heat-flux devices.

The heat source may include one or more processors, GPUs, TPUs, ASICs, FPGAS, memory modules, power semiconductors, insulated-gate bipolar transistors (IGBTs), silicon carbide (SiC) devices, gallium nitride (GaN) devices, battery modules, or any thermally managed component. The heat source may be a cold plate, microchannel heat sink, immersion-cooled assembly, evaporator plate, vapor chamber interface, or any structure configured to transfer heat to a working fluid.

The disclosed vapor quality control concepts may be implemented in closed-loop systems, semi-closed-loop systems, open-loop refrigerant systems, immersion cooling systems, direct-to-chip cooling systems, rack-level systems, row-level systems, facility-level systems, or distributed cooling architectures.

The CDU includes a cooling loop configured to circulate coolant from a cooling apparatus to the heat source and back to the cooling apparatus. The cooling apparatus may include one or more of a condenser, a coolant reservoir, a chiller, and an optional subcooling loop. In certain embodiments, the coolant supplied to the heat source is fully liquid and subcooled, while the coolant exiting the heat source may comprise a mixture of liquid and vapor depending on the instantaneous heat load.

A vapor quality sensor is positioned downstream of the heat source and is configured to measure or estimate a vapor quality (Xe), defined as a ratio of vapor mass to total mass in the liquid-vapor mixture. The vapor quality sensor may be implemented using a capacitive sensor, microwave or radio-frequency sensor, ultrasonic sensor, optical sensor, conductivity sensor, Coriolis mass flow meter, or combinations thereof. The sensor generates a vapor quality signal indicative of the proportion of vapor present in the coolant exiting the heat source.

Control logic, which may be implemented using a programmable logic controller (PLC), microcontroller, industrial computer, processor, or other control circuitry, receives the vapor quality signal and generates a pump control signal. The control logic may be a state machine or other type of controller that executes one or more processes without executing software instructions or may be a processor that fetches and executes software instructions. The control logic may execute stored instructions, apply threshold comparisons, utilize lookup tables, state machines, or predefined control relationships, or combinations thereof, to perform the functions described herein.

As used herein, the terms “control logic” and “controller” refer to structural control circuitry and are not intended to invoke 35 U.S.C. § 112 (f). In illustrative embodiments, the control logic comprises one or more tangible hardware components, as described above, configured to receive signals from physical sensors and to generate control signals for physical actuators. The described functions are implemented by the cooperation of the control circuitry with the associated sensors and pump hardware, rather than by an abstract or purely functional element.

In various embodiments, the control logic may implement proportional (P), proportional-integral (PI), proportional-integral-derivative (PID), model predictive control (MPC), adaptive control, gain-scheduled control, neural-network-based control, fuzzy logic control, state-space control, or hybrid control strategies.

In some embodiments, the control logic maintains vapor quality at a target setpoint. In other embodiments, the control logic maintains vapor quality within a bounded operating window defined by upper and lower thresholds. In still further embodiments, the control logic dynamically adjusts the target vapor quality based on detected heat flux, ambient conditions, system aging, coolant properties, or energy optimization objectives.

The controller may implement feedforward control based on predicted workload demand in addition to feedback control based on measured vapor quality.

The pump control signal adjusts a variable-speed pump that delivers coolant to the heat source. In operation, when the measured vapor quality increases—indicating insufficient liquid mass flow or an approaching dry-out condition—the control logic increases pump speed or flow rate to supply additional liquid coolant. Conversely, when the vapor quality decreases below the desired operating range, indicating excess liquid cooling capacity—the control logic reduces pump speed to improve overall energy efficiency and power usage effectiveness (PUE).

Although several embodiments describe modulation of pump speed, the control logic may additionally or alternatively adjust other flow-regulating components. Such components may include electronically actuated valves, proportional control valves, bypass valves, expansion valves, throttling devices, variable orifice elements, refrigerant metering devices, ejectors, or flow restrictors.

In some embodiments, the control logic may regulate condenser performance by adjusting condenser fan speed, chiller capacity, compressor speed, secondary coolant flow, cooling tower parameters, or heat exchanger bypass flow.

In certain embodiments, both pump speed and one or more valves are modulated in coordination to maintain vapor quality within a stable operating region.

In further embodiments, the CDU includes pressure and temperature sensors positioned upstream and downstream of the heat source. The control logic may adjust pump flow rate based on vapor quality alone or in combination with pressure differentials and temperature differentials across the heat source. This multi-parameter control enables mitigation of flow instabilities associated with dual-phase boiling, including Ledinegg instability, and helps maintain operation near a point of maximum heat transfer coefficient.

The control logic may be configured to maintain vapor quality below a dry-out threshold, near a maximum heat transfer coefficient, or within a predetermined operating window selected to balance thermal performance, reliability, and energy efficiency. In partial-load operating conditions, the control logic may intentionally reduce pump speed to optimize PUE while maintaining safe component temperatures.

Although described primarily in the context of a data center CDU, the disclosed systems and methods may be applied at various levels of granularity, including rack-level, server-level, or component-level cooling architectures. Numerous variations and modifications will be apparent to those skilled in the art and are intended to fall within the scope of the appended claims.

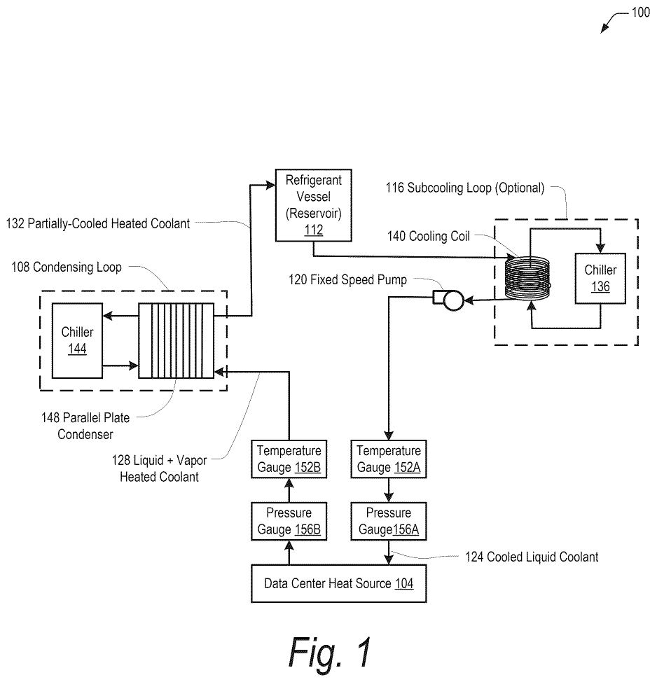

Referring to FIG. 1, a schematic diagram of an example of a dual-phase cooling system 100 in accordance with illustrated embodiments is shown. FIG. 1 illustrates common elements of an exemplary dual-phase cooling system 100 for a data center and may differ across different locations and installations. Dual-stage cooling systems may include fewer or more stages or flow details. As such, FIG. 1 may illustrate an example of a representative system.

The data center computers and other devices may be represented as a “data center heat source” 104 that generates significant heat and needs to be cooled by the dual-phase cooling system 100. The computers may be organized as high-density blade servers and may employ various forms of liquid and/or air cooling within chassis containing the blade servers and other components. The amount of heat generated by the data center heat source 104 may vary depending on the processing load and number/complexity of computing devices.

In one embodiment, a fixed speed pump 120 may supply a cooled liquid coolant 124 to a data center. The data center heat-producing devices 104 transfer heat to the coolant 124 and produce liquid+vapor heated coolant 128. Depending on the current heat produced by the data center, the liquid+vapor heated coolant 128 may be majority liquid through majority vapor. At very low data center processing loads, the liquid+vapor heated coolant 128 may be completely liquid, while at very high data center processing load, the liquid+vapor heated coolant may be completely vapor.

In one embodiment, the temperature and pressure of the cooled liquid coolant 124 may be measured by a first pair of pressure 156A and temperature 152A sensors. The data center heat source 104 applies a variable amount of heating to the cooled liquid coolant 124. Depending on the amount of heating, a portion of the cooled liquid coolant 124 may be converted to a vapor stage. The data center heat source 104 provides liquid+vapor heated coolant 128 to a second pair of pressure 156B and temperature 152B sensors.

A condensing loop 108 receives the liquid and vapor heated coolant 128 and converts the vapor portion back to liquid form. For example, a chiller 144 coupled to a parallel plate condenser 148 condenses the vapor back to liquid form. The partially cooled heated coolant 132 may be provided to a refrigerant vessel or reservoir 112 to store the coolant in liquid form.

In one embodiment, an optional subcooling loop 116 may receive the partially cooled heated coolant 132 from the refrigerant vessel or reservoir 112 and convert the partially-cooled heated coolant 132 to a cooled liquid coolant 124. For example, a chiller 136 coupled to a cooling coil 140 may cool the coolant and provide the cooled coolant 124 to the pump 120.

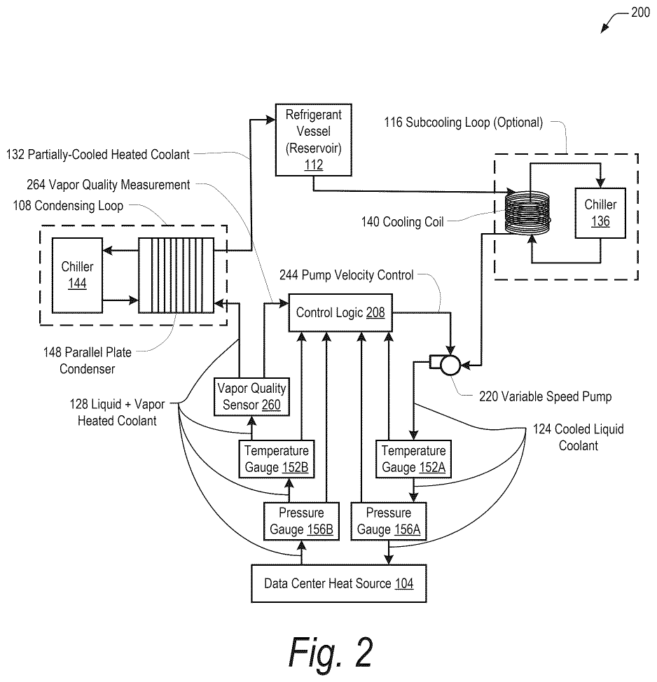

Referring to FIG. 2, a schematic diagram of a dual-phase cooling system 200 in accordance with illustrated embodiments is shown. FIG. 2 illustrates most of the dual-phase cooling system of FIG. 1, but with improvements that may result in improved performance compared with the example system 100 of FIG. 1.

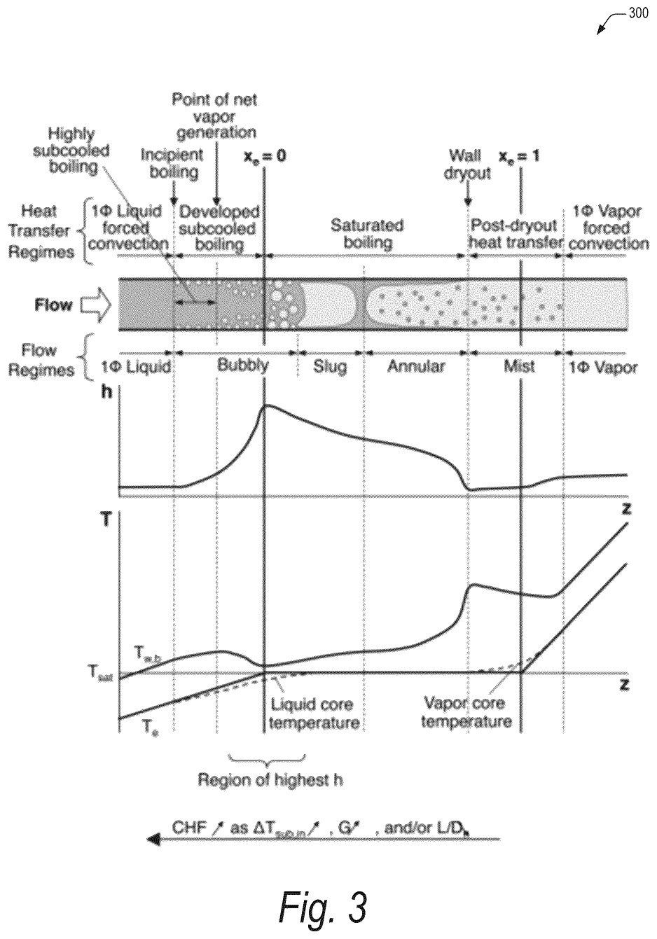

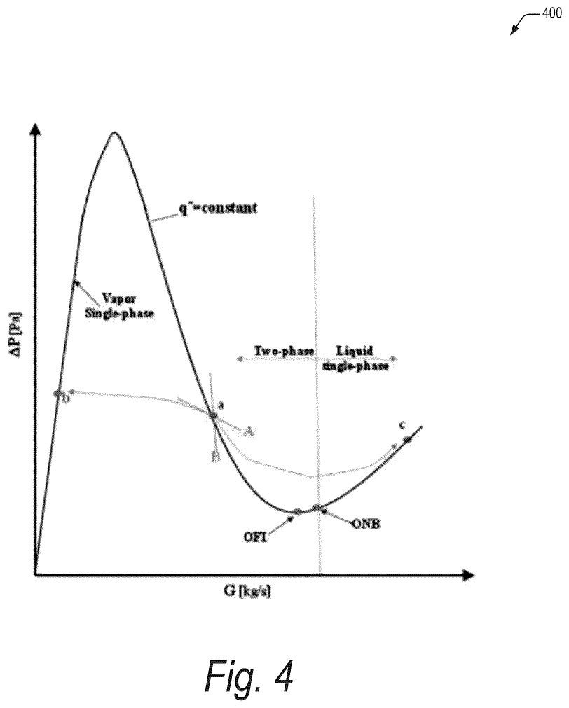

In addition to the first 152A, 156A and second 152B, 156B pressure and temperature sensors, the improved system includes a vapor quality sensor 260 and associated control logic 208. The vapor quality sensor 260 passes the liquid and vapor heated coolant 128 to the condensing loop 108, as before, but the vapor quality sensor 260 provides a vapor quality measurement 264 to the control logic 208. The control logic 208 also receives pressure and temperature measurements at both the cooling input 152A, 156A and cooling output 152B, 156B from the data center. The control logic 208 modulates a variable speed pump 220 through a pump velocity control 244 to vary the flow rate of the cooled liquid coolant 124 according to FIGS. 3 and 4.

A vapor quality (VQ) sensor 260 or a dual-phase flow sensor is a type of sensor that detects the vapor quality of a stream. VQ sensors 260 measure the proportion of vapor and liquid in a flowing mixture, which is essential in industries like power plants, refrigeration, oil & gas, and chemical processing. The present invention may be used with any type of vapor quality sensor 260. There are several types of VQ sensors 260:

Dielectric constant sensors (capacitive sensors) measure the dielectric constant of a liquid, which changes depending on a vapor-to-liquid ratio. These sensors essentially act like a capacitor, where the liquid acts as the dielectric material. A higher capacitance value indicates a higher liquid content (and therefore, a lower vapor quality Xe) within the liquid-vapor mixture. They are frequently used in refrigeration systems to monitor refrigerant quality. An example of a capacitive sensor is a model CS capacitive sensor manufactured by Lake Shore Cryotronics Inc.

Microwave or radio frequency sensors use electromagnetic waves to determine vapor quality based on a liquid-vapor mixture's permittivity and conductivity. They are frequently used in steam pipelogics and chemical processes.

Ultrasonic sensors measure changes in acoustic impedance as sound waves pass through the vapor-liquid mixture. They are frequently used in dual-phase flow pipelogics.

Optical sensors (laser or infrared-based) measure light scattering or absorption to determine vapor fraction. They are frequently used in power plants to ensure steam entering turbines is dry.

Conductivity sensors measure the electrical conductivity of the liquid-vapor mixture, which changes as vapor content increases. They are frequently used in boiler water-steam systems.

In some embodiments, the vapor quality need not be measured by a dedicated vapor quality sensor. Instead, vapor quality may be estimated or inferred using combinations of measured parameters including pressure, temperature, density, dielectric properties, acoustic characteristics, flow velocity, enthalpy, mass flow rate, or combinations thereof.

For example, vapor quality may be estimated using thermodynamic relationships based on measured pressure and temperature relative to a known saturation curve for the coolant. In other embodiments, vapor quality may be derived using mass and energy balance calculations across the heat source. In further embodiments, vapor quality may be inferred using machine-learning models trained on empirical system data.

Accordingly, the term “vapor quality sensor” as used herein may include both direct measurement devices and indirect estimation systems configured to generate a signal indicative of vapor-to-liquid ratio.

Referring to FIG. 3, a graph of critical points of dual-phase microchannel heat transfer 300 in accordance with illustrated embodiments is shown. FIG. 3 illustrates various transfer characteristics of liquid coolant at the data center heat source 104 as it transitions through a dual-phase liquid and vapor to a single phase vapor as it is heated. FIG. 3 shows from top to bottom the coolant behavior, heat transfer regimes, flow, flow regimes, heat transfer coefficient h and temperature T. Xe represents the vapor quality, where Xe=0 represents a liquid state and Xe=1 represents a vapor state. Xe values between 0 and 1 represent a liquid-vapor state with a greater proportion of vapor as Xe approaches a value of 1.

With a subcooled inlet (i.e., cooled liquid coolant from the subcooling loop 116), the liquid flow persists for a finite length until boiling commences due to a locally overheated wall (i.e. a wall of a heat sink the coolant passes through. The heat sink is typically coupled to or in immediate proximity to extreme heat producing components such as CPUs or GPUs of the data center heat source 104). This marks a transition to subcooled boiling, where the overall liquid is still at a subcooled status. The saturated boiling region consists of bubbly, slug, and annular flow, in sequence. This annular flow region persists until a point of wall dry-out (Xe=1). Droplets are still entrained in the vapor downstream from the dry-out point, providing post dry-out mist flow. Eventually, all the droplets are consumed by coolant evaporation and the flow is converted into pure vapor (Xe=1). The heat transfer coefficient (h) is both constant and low in the inlet liquid region. The heat transfer coefficient (h) begins increasing at a point of incipient boiling and reaches a maximum around Xe=0. This is followed by a reduction in the saturated boiling region, reaching a minimum at the dry-out point. FIG. 3 also shows the variation of wall temperature Tw,b along the microchannels. The lowest wall temperatures are encountered in the highly subcooled region and around zero vapor quality Xe. The minimum temperature difference between wall temperature Tw,b and liquid temperature Te can be achieved at the point of Xe=0, which is the position of minimal wall overheat. In other words, at the point of Xe=0, the highest liquid temperature Te can cool the wall to a low temperature by the highest heat transfer coefficient (h). From a heat transfer point of view, this point represents an ideal working condition.

In one embodiment, the control logic 208 is configured to maximize the variable flow rate through the pump velocity control 244 based on a vapor core temperature of the coolant is higher than a saturation temperature of the coolant. This is illustrated at the bottom of FIG. 3, where the vapor core temperature starts to increase during post-dryout heat transfer after the saturated boiling region. The saturation temperature of the coolant may be determined from temperature gauge 152B.

Referring to FIG. 4, a channel demand curve 400 in accordance with illustrated embodiments is shown. In addition to the flow regime of the dual-phase flow shown in FIG. 3, the instability of dual-phase boiling shown in FIG. 4 must be accounted for. Flow boiling in a channel is susceptible to static Ledinegg instability when a slope of the demand pressure-drop-mass flux curve becomes algebraically smaller than a loop supply pressure drop-mass flux curve:

$$\frac{\partial ( Δ P )}{\partial G} {\vert}_{channel demand} \leq \frac{\partial ( Δ P )}{\partial G} {\vert}_{pump supply}$$

Ledinegg instability occurs in dual-phase flow, such as in a boiler tube, when the boiling boundary is within the tube. For a given mass flux through the tube, a pressure drop per unit length (which typically varies as the square of the mass flux and inversely as the density) J2/p is much less when the flow is wholly liquid (Xe=0) than when the flow is wholly vapor (Xe=1). Thus, as the boiling boundary moves up the tube, the total pressure drop falls-potentially increasing the flow in an unstable manner. Boiler tubes normally overcome this (which is effectively a ‘negative resistance’ regime) by incorporating a narrow orifice at the entry, to give a stabilizing pressure drop on entry.

If the pump operates as represented by the A curve, there are three different mass flow (G) rates at points a, b, and c in response to the similar pressure drop (ΔP). It means stable pump mass flow cannot be achieved (the pump mass flow may swing along the curve from b->a->c). On the contrary, if the pump operates in the B curve, point “a” is the unique cross of the pump curve and the fluid curve. The fluid curve (ΔP vs. G) can be explained that as the mass flux is continuously reduced while other conditions are unchanged, boiling will commence at some pressure drop (designated as the onset of nucleate boiling (ONB) on the curve). Further reduction in the mass flux will gradually cause vigorous boiling to occur. Since frictional and accelerational pressure drops tend to increase as the void fraction (and mass quality) increases, a point can be reached in which the ΔP-G slope reaches a minimum. This point has frequently been termed the onset of flow instability (OFI). Beyond this point, any further reduction in the mass flux can cause the flow to become unstable if proper measures are not taken.

The Ledinegg phenomena may be observed in two heated parallel microchannels, where microchannels are relatively narrow tubes that carry the coolant. When both channels are at the single flow regime (subcooling), the wall temperatures of the two microchannels is the same as the result of an even pressure balance between the two microchannels. However, when the fluid moves across the boiling incipience point, Ledinegg instability induces a temperature difference between the two channels due to flow maldistributions. The temperature difference keeps increasing until the boiling incipience occurs in a second channel. For a heat exchanger including multiple microchannels, a trivial difference between microchannels may lead to the emergence of Ledinegg instability in respective microchannels asynchronously-which will result in uneven temperature distribution.

In certain embodiments, the control logic 208 may compute or estimate a stability margin relative to an onset-of-flow-instability (OFI) condition. The controller 208 may use pressure-drop slope analysis, real-time mass flux estimation, or stored demand-curve data to ensure that system operation remains on a stable branch of the pressure-drop versus mass flux curve.

The controller 208 may detect early instability indicators including oscillatory pressure signals, oscillatory vapor quality signals, phase lag between pressure and temperature signals, or divergence between parallel flow channels. Upon detecting such conditions, the controller 208 may proactively increase mass flux, reduce heat load, or adjust operating parameters to return the system to a stable regime.

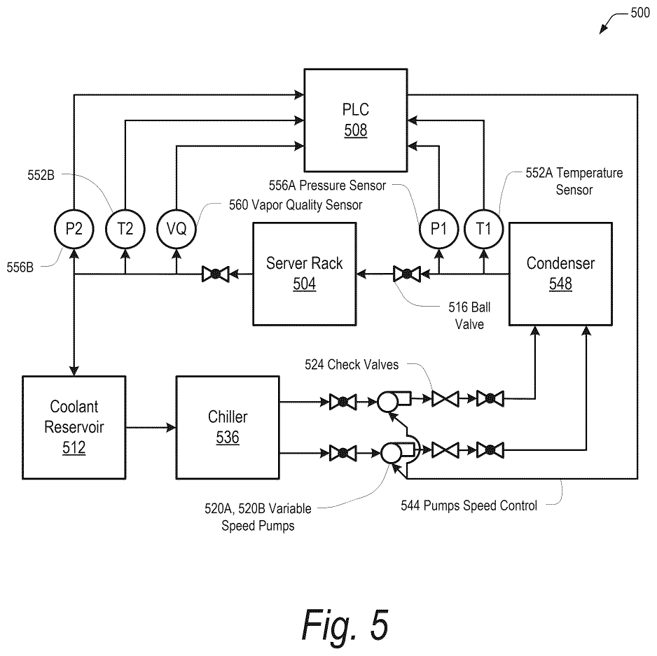

Referring to FIG. 5, a schematic diagram of a dual phase cooling system employing vapor quality control 500 in accordance with illustrated embodiments is shown. A first pair of pressure-temperature sensors “P1” 556A and “T1” 552A monitor pressure and temperature of the coolant input to a server rack 504, and a second pair of pressure-temperature sensors “P2” 556B and “T2” 552B monitor pressure and temperature of the coolant output of the server rack 504. The function of these Pressure/Temperature sensor pairs is to supervise the inlet/outlet status of fluid to heat sources and provide the secondary (assistant) control signals to control the variable pumps speed 544. For example, if the P1-P2 pressures become very high (while Xe is low), it may imply a blockage somewhere in the system. If the P1-P2 pressures become very high (while Xe is high), it may imply the heat load is much higher than the computing load (i.e., data center or server rack 504 heat source load). A possible solution is to open a motorized valve on a utility water supply logic to bring down the T1-T2 temperatures. If the T1-T2 temperatures become very high, then the P1-P2 pressures are high and Xe from the vapor quality sensor 560 is high That indicates that the liquid supply is insufficient. This indicates that pump speed 544 cannot be controlled only by two sets of Pressure/Temperature sensors. This is the reason why in conventional systems there is no control of pump speed. It also indicates that the pump speed control 544 cannot solely rely on the Xe, it must be controlled under the assistance of two pairs of Pressure/Temperature sensors P1/T1 552A/556A and P2/T2 552B/556B.

FIG. 5 illustrates a vapor Quality (VQ) sensor 560 installed in an exit logic from the server rack 504, allowing for real-time detection of the exit vapor quality. The sensor's signal is input to a programmable PLC 508 (analogous to the control logic 208 shown and described with reference to FIG. 2) along with measurements from pressure sensors P1-P2 and temperature sensors T1-T2, which can dynamically adjust the pump speed 544 to maintain optimal system performance.

The PLC 508 aims to maintain a stable vapor quality Xe by dynamically adjusting the pump speed 544. When the vapor quality exceeds the desired threshold—indicating that the supplied mass flow is insufficient to fully cool the server rack 504, resulting in more vapor in the return logic—the PLC 508 increases the pump speed 544 to raise the liquid supply flow and prevent overheating. Conversely, when the vapor quality Xe drops—implying that the supplied liquid exceeds the cooling demands of the hot spots—the pump speed 544 is reduced by the PLC 508 to optimize cooling capacity. This closed-loop control mechanism ensures system stability and maintains optimal PUE under varying thermal loads. In one embodiment the PLC 508 or system 500 may store a time-correlated record that includes a value of the vapor quality signal, predetermined vapor quality threshold values, and a corresponding pump speed command.

In certain embodiments, the control logic 508 communicates with a building management system (BMS), data center infrastructure management (DCIM) platform, cloud-based supervisory controller, or remote monitoring system. Vapor quality data and pump control data may be transmitted over wired or wireless networks using industrial communication protocols.

In a practical embodiment, the system 500 may contain multiple variable speed pumps 520A, 520B and associated valves 516, 524 to provide redundancy in case of pump 520 failure. In the data center industry, if one pump 520A serves as a primary pump, a redundant pump 520B is required as a backup to ensure system reliability and uptime. In most cases multiple pumps 520A, 520B may operate in a rotation mode to balance wear and extend pump lifetime.

In some embodiments, the control system 500 includes fault-detection logic configured to detect sensor failure, pump(s) 520 failure, valve(s) 524 malfunction, abnormal pressure differential, or abnormal temperature gradient.

If the vapor quality sensor 560 becomes unavailable or unreliable, the control logic 508 may transition to a fallback mode in which pump control 544 is based on pressure and temperature differentials alone.

In certain embodiments, the system 500 may implement safe operating modes in which pump speed 544 is driven to a conservative value to prevent dry-out or overheating until normal sensor operation is restored.

Regardless of the cost of the vapor quality (VQ) sensor 560, this control mechanism can be implemented at various levels, from the CDU 500 level (with the VQ sensor 560 installed only in the CDU 500) to the server level (with a VQ sensor 560 installed in each server of server racks 504 of a data center). The server-level application requires the use of modulation valves to control the mass flow into each server, enabling solutions to two critical challenges: correcting mass flow maldistribution between servers located at different heights and achieving temperature-independent control across servers. Currently, there are very limited approaches available to adapt the mass flow based on varying requirements of servers within the same cooling loop.

In some embodiments, vapor quality control may be implemented at multiple hierarchical levels. For example, a facility-level CDU may regulate aggregate vapor quality, while individual rack-level or server-level controllers regulate local vapor quality using distributed sensors and modulating valves.

In certain embodiments, individual servers within a rack may include independent vapor quality sensors and flow modulation valves that enable per-server mass flow optimization. This architecture permits correction of gravitational head differences, elevation-based pressure variations, and non-uniform heat loads across vertically stacked servers.

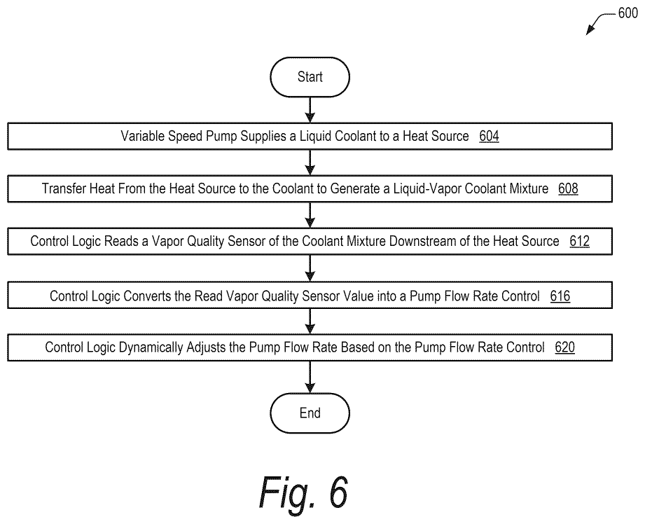

Referring to FIG. 6, a flowchart of a flow rate control process of a CDU 600 in accordance with a first illustrated embodiment is shown. In the first embodiment, a dedicated vapor quality sensor is used to determine vapor quality and adjust pump flow rate based on vapor quality. Flow begins at block 604.

At block 604, one or more variable speed pumps 520 supply a liquid coolant to a heat source. The liquid coolant may be a dielectric fluid and the heat source may be one or more electronic components or heat sinks affixed to a server motherboard. Flow proceeds to block 608.

At block 608, heat is transferred from the heat source to the coolant to generate a liquid-vapor coolant mixture. A portion of the liquid coolant is converted to a vapor coolant when the heat is transferred to the coolant. Flow proceeds to block 612.

At block 612, control logic (e.g., programmable logic controller or PLC 508) associated with the CDU 500 measures the vapor quality of the liquid-vapor coolant mixture downstream (i.e. in the direction of) the heat source. The vapor quality sensor 560 produces a vapor quality value that is read by the control logic 508 and possibly conditioned, normalized, or is otherwise prepared for comparison. Flow proceeds to block 616.

At block 616, the control logic 508 converts the conditioned read vapor quality sensor value into a pump flow rate control 544. The conversion may be provided by a look-up table that cross-references conditioned vapor quality sensor data values with pump flow rate control values. In another embodiment, the control logic 508 may execute an algorithm or formula that produces the pump flow rate control value 544. Flow proceeds to block 620.

At block 620, the control logic 508 dynamically adjusts (i.e. in real time) the pump(s) flow rate based on the pump flow rate control 544. Flow ends at block 620.

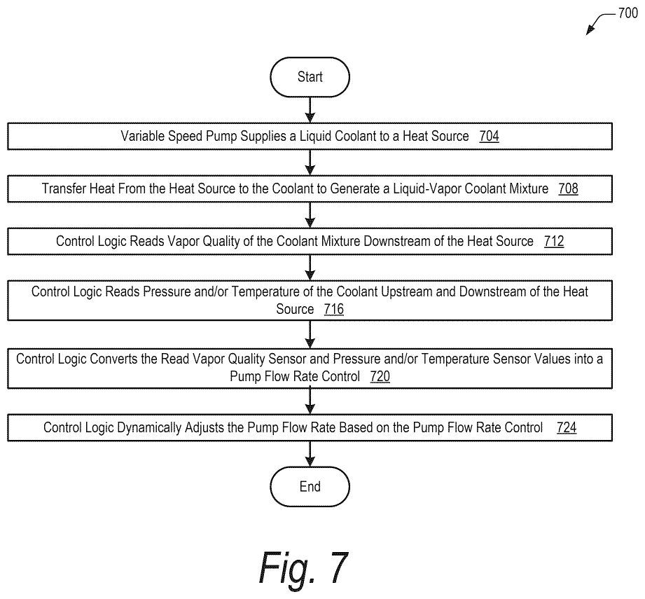

Referring to FIG. 7, a flowchart of a flow rate control process of a CDU 700 in accordance with a second illustrated embodiment is shown. In the second embodiment, a dedicated vapor quality sensor 560 is combined with a pair of pressure 556 and/or temperature 552 sensors to determine vapor quality and adjust pump flow rate based on vapor quality. Flow begins at block 704.

At block 704, one or more variable speed pumps 520 supply a liquid coolant to a heat source 504. The liquid coolant may be a dielectric fluid and the heat source may be one or more electronic components or heat sinks affixed to a server motherboard within a server rack 504. Flow proceeds to block 708.

At block 708, heat is transferred from the heat source 504 to the coolant to generate a liquid-vapor coolant mixture. A portion of the liquid coolant is converted to a vapor coolant when the heat is transferred to the coolant. Although reference is made to CDU elements shown in FIG. 5, they are equally applicable to the embodiment illustrated in FIG. 2. Flow proceeds to block 712.

At block 712, control logic (e.g., programmable logic controller or PLC 508) associated with the CDU 500 measures the vapor quality of the liquid-vapor coolant mixture downstream (i.e. in the direction of) the heat source 504. The vapor quality sensor 560 produces a vapor quality value that is read by the control logic 508 and possibly conditioned, normalized, or is otherwise prepared for comparison. Flow proceeds to block 716.

At block 716, the control logic 508 reads pressure 556 and/or temperature 552 sensors of the coolant upstream and downstream the heat source 504. In one embodiment, the pressure 556 and/or temperature 552 sensor values may be conditioned or normalized or otherwise prepared for comparison. Flow proceeds to block 720.

At block 720, the control logic 508 converts the conditioned read vapor quality sensor 560 and the conditioned pressure 556 and/or temperature 552 sensor values into a pump flow rate control 544. The conversion may be provided by a look-up table that cross-references conditioned vapor quality sensor 560 and pressure and/or temperature data values with pump flow rate control values. In another embodiment, the control logic 508 may execute an algorithm or formula that produces the pump flow rate control values. Flow proceeds to block 724.

At block 724, the control logic 508 dynamically adjusts (i.e. in real time) the pump(s) flow rate based on the pump flow rate control 544. Flow ends at block 724.

In some embodiments, adjusting the flow rate includes adjusting mass flux to maintain operation near a vapor quality corresponding to peak heat transfer coefficient.

In other embodiments, adjusting the flow rate comprises intentionally operating at a vapor quality offset from the peak heat transfer coefficient to maintain a desired reliability margin.

In certain embodiments, the method further includes predicting future heat load based on computational workload scheduling and preemptively adjusting pump speed prior to vapor quality deviation.

In further embodiments, the method includes storing historical vapor quality data and using trend analysis to detect fouling, degradation of heat transfer surfaces, coolant contamination, or pump performance drift.

The coolant may include dielectric fluids, refrigerants, hydrofluorolefins (HFOs), hydrofluorocarbons (HFCs), hydrocarbons, water, water-glycol mixtures, ammonia, carbon dioxide, engineered fluids, nanofluids, or other single-component or multi-component working fluids.

The coolant may operate in subcooled boiling, saturated boiling, annular flow, mist flow, or superheated vapor regimes.

The disclosed control techniques apply to microchannel heat sinks, microchannel systems, jet impingement systems, spray cooling systems, immersion cooling systems, and thermosyphon-based systems employing active circulation.

The embodiments described above are intended to be merely exemplary; numerous variations and modifications will be apparent to those skilled in the art. All such variations and modifications are intended to be within the scope of the present disclosure as defined in any appended innovations.

What is claimed is:

1. A cooling distribution unit for dual-phase cooling of electronic equipment, comprising:
a cooling loop configured to circulate a coolant to and from a heat source;
a condenser configured to condense vaporized coolant into liquid coolant;
a variable-speed pump configured to deliver the liquid coolant to the heat source;
a vapor quality sensor positioned downstream of the heat source and configured to generate a vapor quality signal indicative of a vapor-to-liquid ratio of coolant exiting the heat source;
one or more pressure sensors and/or temperature sensors positioned upstream and downstream of the heat source; and
control logic operatively coupled to the vapor quality sensor, the one or more pressure and/or temperature sensors, and the variable-speed pump,
wherein the control logic is configured to adjust a flow rate of the pump based on the vapor quality signal, alone or in combination with pressure and/or temperature signals, to maintain operation of the cooling loop within a stable dual-phase operating region corresponding to a predetermined vapor quality range.

2. The cooling distribution unit of claim 1, wherein the one or more pressure sensors and/or temperature sensors include at least one pressure sensor and at least one temperature sensor positioned upstream of the heat source and at least one pressure sensor and at least one temperature sensor positioned downstream of the heat source.

3. The cooling distribution unit of claim 1, wherein the control logic adjusts the flow rate of the pump based on the vapor quality signal in combination with a pressure differential and/or a temperature differential across the heat source.

4. The cooling distribution unit of claim 1, wherein the predetermined vapor quality range corresponds to a vapor quality region associated with a maximum heat transfer coefficient of the coolant.

5. The cooling distribution unit of claim 1, wherein the control logic increases the flow rate of the pump in response to the vapor quality signal indicating movement toward a dry-out condition downstream of the heat source.

6. The cooling distribution unit of claim 1, wherein the control logic decreases the flow rate of the pump in response to the vapor quality signal indicating excess liquid cooling capacity.

7. The cooling distribution unit of claim 1, wherein the control logic is configured to adjust the flow rate of the pump to maintain a stability margin relative to a dual-phase flow instability condition.

8. The cooling distribution unit of claim 1, wherein the control logic generates the pump speed control based on a stored relationship between vapor quality and coolant mass flux defining a stable operating region of the cooling loop.

9. The cooling distribution unit of claim 1, further comprising a subcooling loop configured to supply subcooled liquid coolant to the variable-speed pump.

10. A method for controlling dual-phase cooling of electronic equipment with a cooling distribution unit (CDU), comprising:
supplying liquid coolant to a heat source using a variable-speed pump of the CDU;
transferring heat from the heat source to the coolant to generate a liquid-vapor coolant mixture exiting the heat source;
measuring a vapor quality of the liquid-vapor coolant mixture downstream of the heat source to generate a vapor quality signal;
measuring one or more of pressure or temperature of the coolant upstream and downstream of the heat source; and
adjusting a flow rate of the variable-speed pump, by control logic of the CDU, based on the vapor quality signal alone or in combination with the measured pressure or temperature, to maintain operation of the CDU within a stable dual-phase operating region corresponding to a predetermined vapor quality range.

11. The method of claim 10, wherein measuring one or more of pressure or temperature comprises measuring pressure and temperature of the coolant upstream of the heat source and pressure and temperature of the coolant downstream of the heat source.

12. The method of claim 10, wherein adjusting the flow rate of the variable-speed pump is based on the vapor quality signal in combination with at least one of a pressure differential or a temperature differential across the heat source.

13. The method of claim 10, wherein adjusting the flow rate maintains the vapor quality of the coolant below a dry-out threshold downstream of the heat source.

14. The method of claim 10, wherein the predetermined vapor quality range corresponds to a vapor quality region associated with a maximum heat transfer coefficient of the coolant.

15. The method of claim 10, further comprising:
condensing vaporized coolant exiting the heat source;
storing the condensed coolant in a coolant reservoir of the CDU; and
recirculating the stored condensed coolant to the heat source.

16. The method of claim 10, wherein adjusting the flow rate of the variable-speed pump comprises increasing the flow rate in response to the vapor quality exceeds an upper vapor quality threshold.

17. A control system for a dual-phase cooling loop, comprising:
a vapor quality sensor positioned downstream of a heat source and configured to generate a vapor quality signal (Xe) indicative of a vapor-to-liquid ratio of a coolant exiting the heat source;
one or more pressure sensors and/or temperature sensors positioned upstream and downstream of the heat source and configured to generate pressure signals and/or temperature signals indicative of coolant operating conditions across the heat source;
a controller operatively coupled to the vapor quality sensor and the one or more pressure sensors and/or temperature sensors, the controller being configured to:
receive the vapor quality signal and the pressure signals and/or temperature signals;
compare the vapor quality signal to one or more predetermined vapor quality threshold values defining an operating range;
generate a pump speed command for a variable-speed pump that adjusts a coolant flow rate through the heat source as a function of the received vapor quality signal and the pressure signals and/or temperature signals; and
store or log one or more of the vapor quality signal or the predetermined vapor quality threshold values in association with the generated pump speed command.

18. The control system of claim 17, wherein the controller is configured to increase the pump speed command in response to the vapor quality signal exceeds an upper vapor quality threshold and to decrease the pump speed command when the vapor quality signal falls below a lower vapor quality threshold.

19. The control system of claim 17, wherein the controller is configured to modify the pump speed command based on the vapor quality signal in combination with at least one of a pressure differential or a temperature differential measured across the heat source to mitigate dual-phase flow instability.

20. The control system of claim 17, wherein the controller is further configured to store a time-correlated record including the vapor quality signal, the predetermined vapor quality threshold values, and the corresponding pump speed command.
